(19) United States
(12) Patent Application Publication
(10) Pub. No.: US 2026/0020299 A1
(43) Pub. Date: Jan. 15, 2026

(54) THREE-DIMENSIONAL STACKED TRANSISTOR DEVICE HAVING A PARTIAL BOTTOM DIELECTRIC ISOLATION LAYER AND A PUNCH THROUGH STOPPER LAYER AND A METHOD OF MANUFACTURING THE SAME

(71) Applicant: Samsung Electronics Co., Ltd., Suwon-si (KR)

(72) Inventors: Woosung Choi, Milpitas, CA (US); Hyeon-Kyun Noh, Pleasanton, CA (US)

(21) Appl. No.: 19/085,833

(22) Filed: Mar. 20, 2025

Related U.S. Application Data
(60) Provisional application No. 63/670,100, filed on Jul. 11, 2024.

(51) Int. Cl. H10D 62/10; H10D 84/01; H10D 84/83; H10D 84/85

(52) U.S. Cl. CPC H10D 62/116; H10D 84/0151; H10D 84/832; H10D 84/851

(57) ABSTRACT

A three-dimensional stacked field-effect transistor including a silicon substrate; a partial bottom dielectric isolation layer on the silicon substrate; a punch through stopper layer on the silicon substrate and on opposite sides of the partial bottom dielectric isolation layer; a first transistor on the partial bottom dielectric isolation layer and the punch through stopper layer; and a second transistor stacked on the first transistor. Each of the first transistor and the second transistor includes a channel, a source region on one side of the channel, and a drain region on another side of the channel. The partial bottom dielectric isolation layer is below the channel of the first transistor. The punch through stopper layer is below the source region and the drain region of the first transistor.

### CROSS-REFERENCE TO RELATED APPLICATION(S)

The present application claims priority to and the benefit of U.S. Provisional Application No. 63/670,100, filed Jul. 11, 2024, the entire content of which is incorporated herein by reference.

### BACKGROUND

### 1. Field

The present disclosure relates to three-dimensional stacked transistor devices.

### 2. Description of the Related Art

Complementary field-effect transistors (CFETs) have a three-dimensional transistor architecture including an n-type FET (nFET) stacked on a p-type FET (pFET) or a pFET stacked on an nFET. Stacking the nFET and the pFET, rather than arranging them side-by-side, allows for space savings and transistor scaling. Related art CFETs suffer from bottom leakage due to parasitic channel. Providing a full bottom dielectric isolation (BDI) layer between the lower FET (e.g., the nFET or the pFET) and the substrate can reduce bottom leakage suffer, but it can also reduce thermal dissipation.

The above information disclosed in this Background section is only for enhancement of understanding of the background of the invention and therefore it may contain information that does not constitute prior art.

### SUMMARY

The present disclosure relates to various aspects and embodiments of a method of manufacturing a transistor device. In one embodiment, the method includes forming a channel region of at least a first transistor on a sacrificial layer on a substrate, removing portions of the sacrificial layer, epitaxially growing a punch through stopper layer on the silicon substrate and on opposite sides of a remaining portion of the sacrificial layer, epitaxially growing a source region and a drain region of the first transistor on the punch through stopper layer, and forming a partial bottom dielectric isolation layer including removing the remaining portion of the sacrificial layer to form at least one void.

The transistor device may be a complementary field-effect transistor (CFET), and forming the channel region may include forming a first channel region of the first transistor and a second channel region of a second transistor stacked on the first transistor.

The transistor device may be a single layer field-effect transistor, such as a single nanosheet field-effect transistor.

The method may include substantially filling the at least one void with a dielectric material.

The partial bottom dielectric isolation layer may not extend under the source region or the drain region of the first transistor.

The source region and the drain region of the first transistor may each include p-doped SiGe, and the punch through stopper layer may include n-doped SiGe.

The source region and the drain region of the first transistor may each include n-doped SiGe, and the punch through stopper layer may include p-doped SiGe.

The source region and the drain region of the first transistor may each include p-doped silicon, and the punch through stopper layer may include n-doped silicon.

The source region and the drain region of the first transistor may each include n-doped silicon, and the punch through stopper layer may include p-doped silicon.

The present disclosure also relates to various aspects and embodiments of a field-effect transistor. In one embodiment, the field-effect transistor includes a silicon substrate; a partial bottom dielectric isolation layer on the silicon substrate; a punch through stopper layer on the silicon substrate and on opposite sides of the partial bottom dielectric isolation layer; and a first transistor on the partial bottom dielectric isolation layer and the punch through stopper layer. The first transistor includes a channel, a source region on one side of the channel, and a drain region on another side of the channel. The partial bottom dielectric isolation layer is below the channel of the first transistor. The punch through stopper layer is below the source region and the drain region of the first transistor.

The field-effect transistor may be complementary field-effect transistor (CFET) and may include a second transistor stacked on the first transistor.

The field-effect transistor may be a single layer field-effect transistor, such as a single nanosheet field-effect transistor.

The partial bottom dielectric isolation layer may include a dielectric material.

The partial bottom dielectric isolation layer may include a void.

The partial bottom dielectric isolation layer may not extend under the source region or the drain region of the first transistor.

The first transistor may be a p-type field-effect transistor and the second transistor may be an n-type field-effect transistor.

The source region and the drain region of the first transistor may each include p-doped SiGe, and the punch through stopper layer may include n-doped SiGe.

The source region and the drain region of the first transistor may each include p-doped silicon, and the punch through stopper layer may include n-doped silicon.

The first transistor may be an n-type field-effect transistor and the second transistor may be a p-type field-effect transistor.

The source region and the drain region of the first transistor may each include n-doped SiGe, and the punch through stopper layer may include p-doped SiGe.

The source region and the drain region of the first transistor may each include n-doped silicon, and the punch through stopper layer may include p-doped silicon.

This summary is provided to introduce a selection of concepts that are further described below in the detailed description. This summary is not intended to identify key or essential features of the claimed subject matter, nor is it intended to be used in limiting the scope of the claimed subject matter. One or more of the described features may be combined with one or more other described features to provide a workable device.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

The features and advantages of embodiments of the present disclosure will be better understood by reference to the following detailed description when considered in conjunction with the accompanying figures. In the figures, like reference numerals are used throughout the figures to reference like features and components. The figures are not necessarily drawn to scale.

FIGS. 1A-1B are a perspective view and a cross-sectional view, respectively, of a three-dimensional stacked transistor device including a partial bottom dielectric isolation layer and a punch through stopper layer according to one embodiment of the present disclosure;

FIGS. 2A-2B are perspective views illustrating the three-dimensional stacked transistor device of FIGS. 1A-1B be arranged into an inverter configuration and a static random-access memory (SRAM) configuration, respectively;

FIG. 3 is a flowchart illustrating tasks of a method of manufacturing a three-dimensional stacked transistor device including a partial bottom dielectric isolation layer and a punch through stopper layer according to one embodiment of the present disclosure;

FIGS. 4A-4H depict tasks of manufacturing the three-dimensional stacked transistor device according to the embodiment of the method depicted in FIG. 3;

FIG. 5 is a graph depicting the drain current (Id) as a function of gate voltage (Vg) for a related art transistor device compared to a three-dimensional stacked transistor device according to one embodiment of the present disclosure; and

FIGS. 6A-6B are heat maps depicting the lattice temperature for a related art transistor device having a full bottom dielectric insulation layer and the lattice temperature for a three-dimensional stacked transistor device according to one embodiment of the present disclosure, respectively.

### DETAILED DESCRIPTION

The present disclosure relates to various embodiments of a three-dimensional stacked transistor device (e.g., a complementary field-effect transistor (CFET)) including a lower transistor device, an upper transistor device stacked on the lower transistor device, a partial bottom dielectric isolation (BDI) layer below the channel region of the lower transistor device, and a punch through stopper (PTS) layer below the source/drain regions of the lower transistor device. The partial PTS layer is configured to improve leakage current of the transistor device compared to a related art CFET. The partial BDI layer is configured to improve thermal dissipation compared to a related art transistor device having a full BDI layer that extends underneath the source/drain regions.

Hereinafter, example embodiments will be described in more detail with reference to the accompanying drawings, in which like reference numbers refer to like elements throughout. The present invention, however, may be embodied in various different forms, and should not be construed as being limited to only the illustrated embodiments herein. Rather, these embodiments are provided as examples so that this disclosure will be thorough and complete, and will fully convey the aspects and features of the present invention to those skilled in the art. Accordingly, processes, elements, and techniques that are not necessary to those having ordinary skill in the art for a complete understanding of the aspects and features of the present invention may not be described. Unless otherwise noted, like reference numerals denote like elements throughout the attached drawings and the written description, and thus, descriptions thereof may not be repeated.

In the drawings, the relative sizes of elements, layers, and regions may be exaggerated and/or simplified for clarity. Spatially relative terms, such as “beneath,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present invention.

It will be understood that when an element or layer is referred to as being “on,” “connected to,” or “coupled to” another element or layer, it can be directly on, connected to, or coupled to the other element or layer, or one or more intervening elements or layers may be present. In addition, it will also be understood that when an element or layer is referred to as being “between” two elements or layers, it can be the only element or layer between the two elements or layers, or one or more intervening elements or layers may also be present.

The terminology used herein is for the purpose of describing particular embodiments and is not intended to be limiting of the present invention. As used herein, the singular forms “a” and “an” are intended to include the plural forms as well, unless the context clearly indicates otherwise. It will be further understood that the terms “comprises,” “comprising,” “includes,” and “including,” when used in this specification, specify the presence of the stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. Expressions such as “at least one of,” when preceding a list of elements, modify the entire list of elements and do not modify the individual elements of the list.

As used herein, the term “substantially,” “about,” and similar terms are used as terms of approximation and not as terms of degree, and are intended to account for the inherent variations in measured or calculated values that would be recognized by those of ordinary skill in the art. Further, the use of “may” when describing embodiments of the present invention refers to “one or more embodiments of the present invention.” As used herein, the terms “use,” “using,” and “used” may be considered synonymous with the terms “utilize,” “utilizing,” and “utilized,” respectively. Also, the term “exemplary” is intended to refer to an example or illustration.

Unless otherwise defined, all terms (including technical and scientific terms) used herein have the same meaning as commonly understood by one of ordinary skill in the art to which the present invention belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

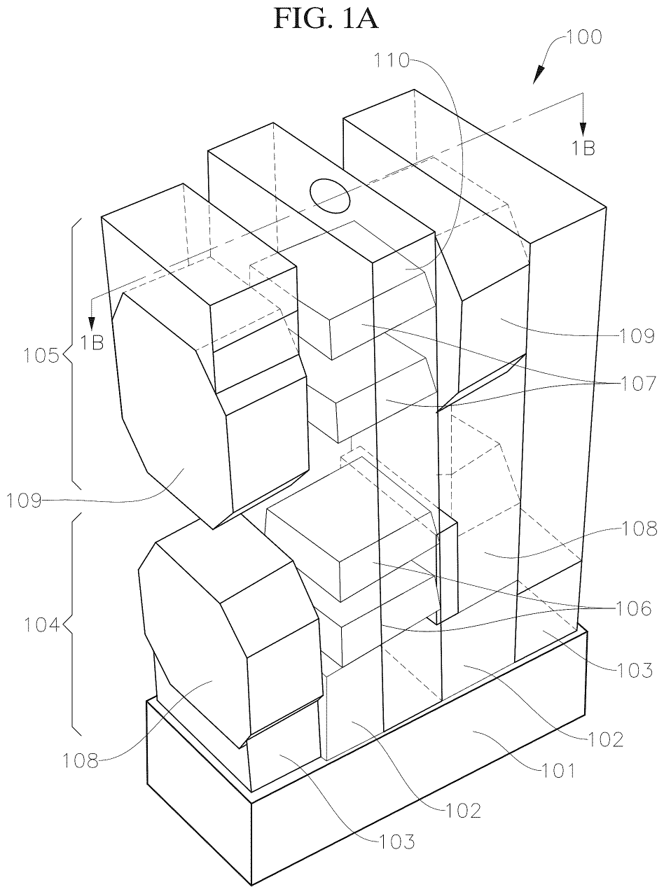

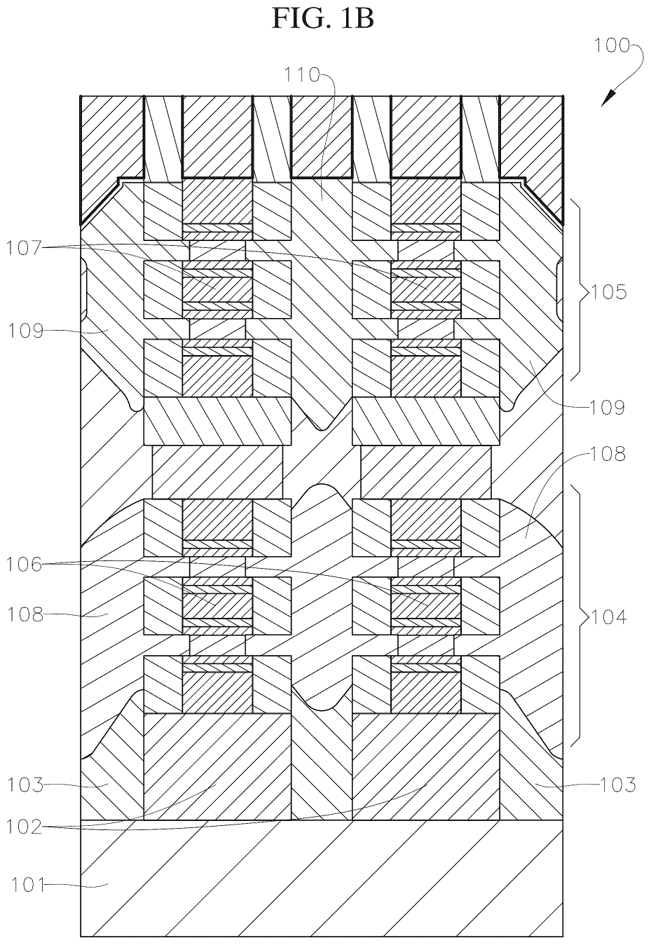

With reference now to FIGS. 1A-1B, a three-dimensional stacked transistor device 100 according to one embodiment of the present disclosure includes a silicon substrate 101, a partial bottom dielectric isolation (BDI) layer 102 on (e.g., directly or indirectly on an upper surface of) the silicon substrate 101, a punch through stopper (PTS) layer 103 on (e.g., directly or indirectly on an upper surface of) the silicon substrate 101 and on opposite sides of the partial BDI layer 102, a first transistor (e.g., a bottom or lower transistor) 104 on the partial BDI layer 102 and the PTS layer 103, and a second transistor (e.g., a top or upper transistor) 105 stacked on the first transistor 104. Each of first transistor 104 and the second transistor 105 includes a channel region 106, 107, respectively, and source/drain regions 108, 109, respectively, on opposite sides of the respective channel region 106, 107. In one or more embodiments, the three-dimensional stacked transistor device 100 also includes a shared gate 110 connected to the channel regions 106, 107 of the first and second transistors 104, 105. The partial BDI layer 102 is below (underneath) the channel region 106 of the first transistor 104 (e.g., the partial BDI layer 102 extends from the silicon substrate 101 to a lower surface of the channel region 106 of the first transistor 104). In one or more embodiments, unlike a full BDI layer, the partial BDI layer 102 does not extend under (or at least substantially does not extend under) the source/drain regions 108 of the first transistor 104. Additionally, in one or more embodiments, the PTS layer 103 is below the source/drain regions 108 of the first transistor 104 (e.g., the partial PTS layer 103 extends from the silicon substrate 101 to lower surfaces of the source/drain regions 108 of the first transistor 104).

In one or more embodiments, the first transistor 104 (i.e., the bottom or lower transistor) may be an n-type field-effect transistor (nFET) and the second transistor 105 (i.e., the top or upper transistor) may be a p-type field-effect transistor (pFET). In one or more embodiments, the first transistor 104 (i.e., the bottom or lower transistor) may be an p-type field-effect transistor (pFET) and the second transistor 105 (i.e., the top or upper transistor) may be an n-type field-effect transistor (nFET). In one or more embodiments in which the PTS layer 103 is n-type doped, the source/drain regions 108 of the first transistor 104 are p-type doped. In one or more embodiments, the source/drain regions 108 of the first transistor 104 each include p-doped SiGe, and the PTS layer 103 includes n-doped SiGe. In one or more embodiments, the source/drain regions 108 of the first transistor 104 each include n-doped SiGe, and the PTS layer 103 includes p-doped SiGe. In one or more embodiments, the source/drain regions 108 of the first transistor 104 each include p-doped silicon, and the PTS layer 103 includes n-doped silicon. In one or more embodiments, the source/drain regions 108 of the first transistor 104 each include n-doped silicon, and the PTS layer 103 includes p-doped silicon.

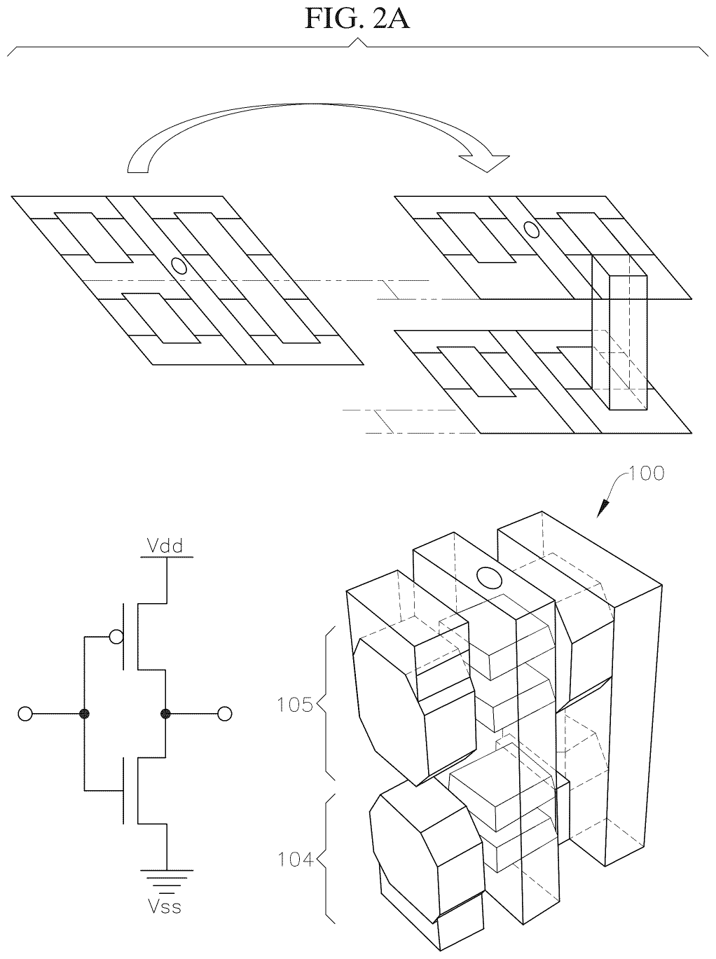

Additionally, in one or more embodiments, the first and second transistors 104, 105 may be arranged in an inverter configuration, as shown in FIG. 2A, or in a static random-access memory (SRAM) configuration (i.e., six transistors 104, 105 arranged in a flip-flop circuit), as shown in FIG. 2B. In one or more embodiments, as shown in FIGS. 2A-2B, the configuration of the three-dimensional stacked transistor device 100 may result in transistor density scaling in a range from approximately 1.5× to approximately 2× (i.e., approximately 50% to approximately 100% greater transistor density) compared to a related art transistor device.

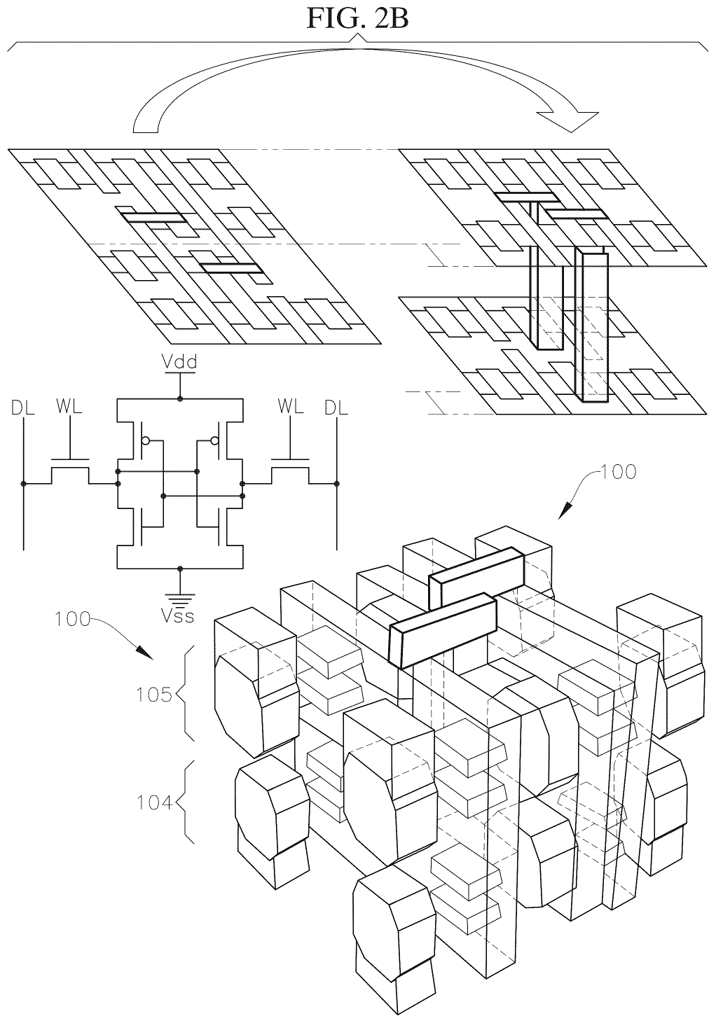

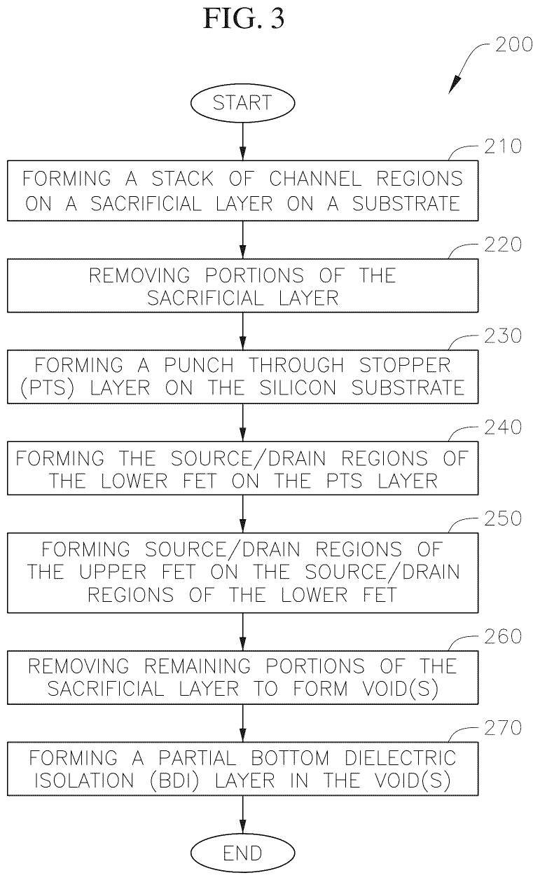

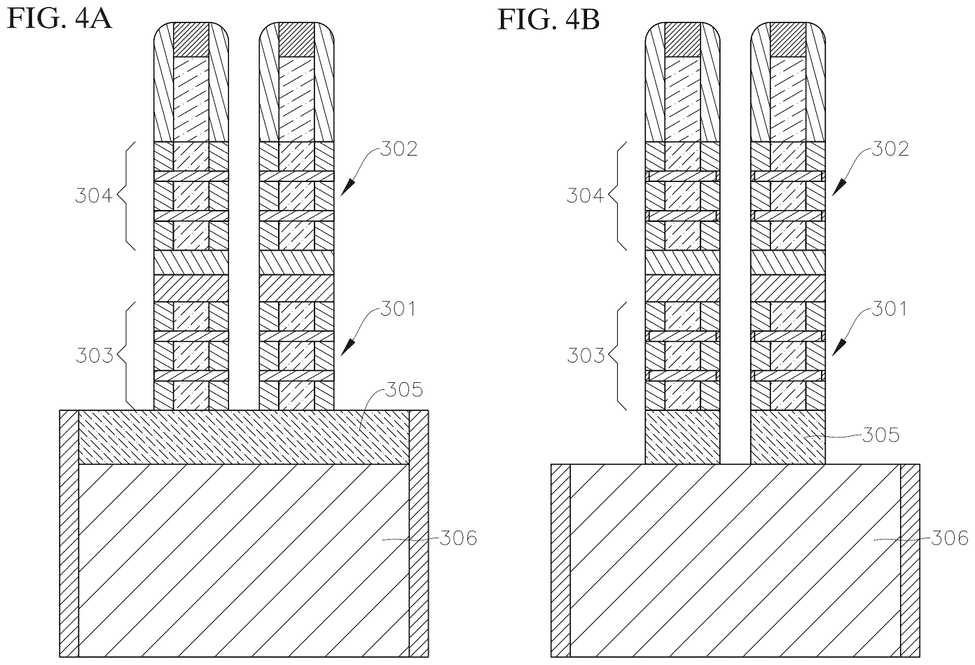

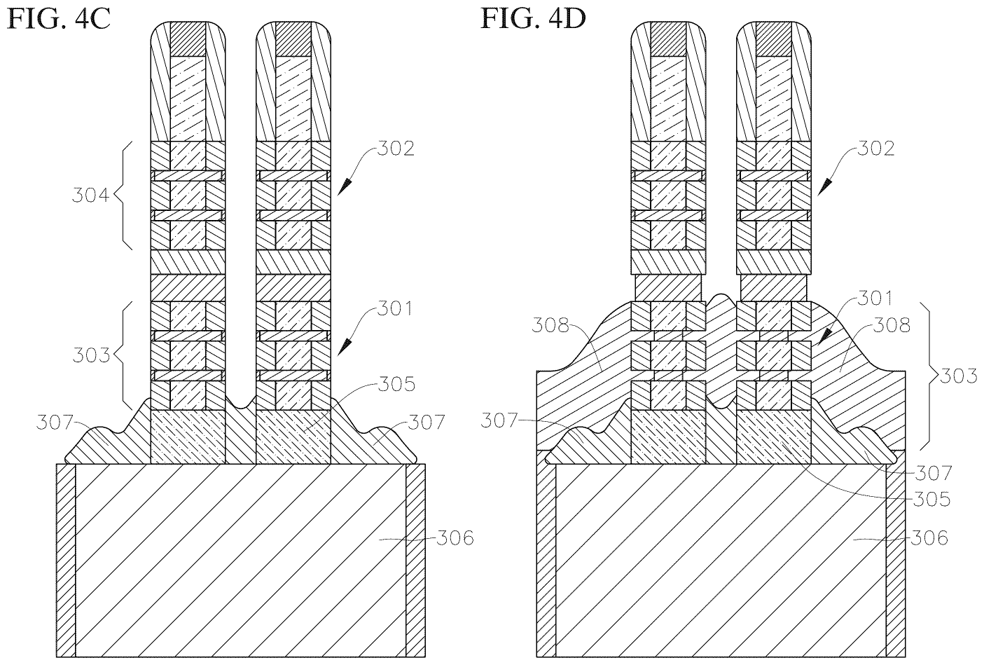

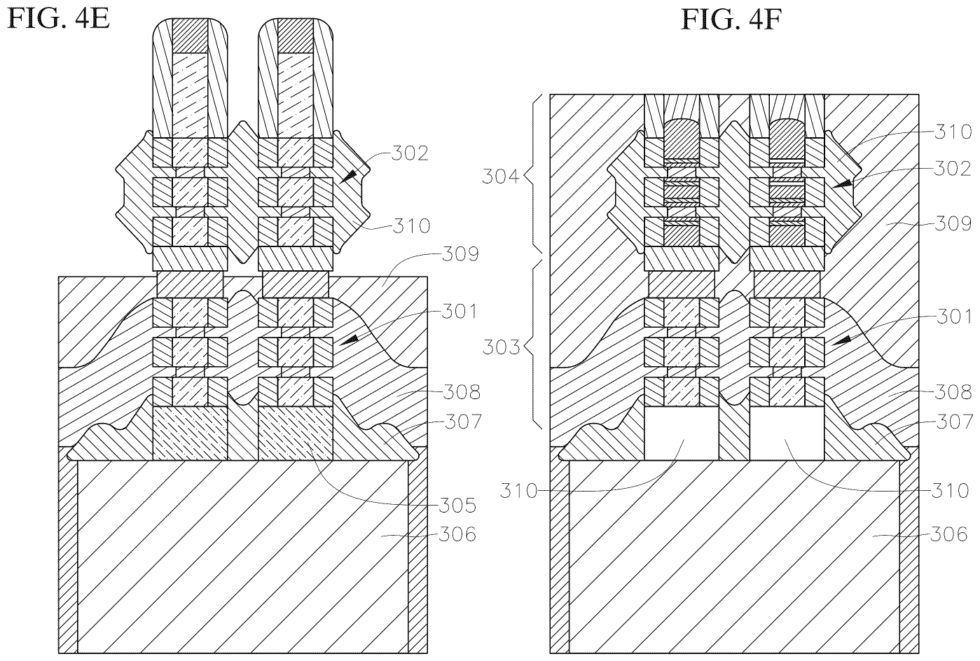

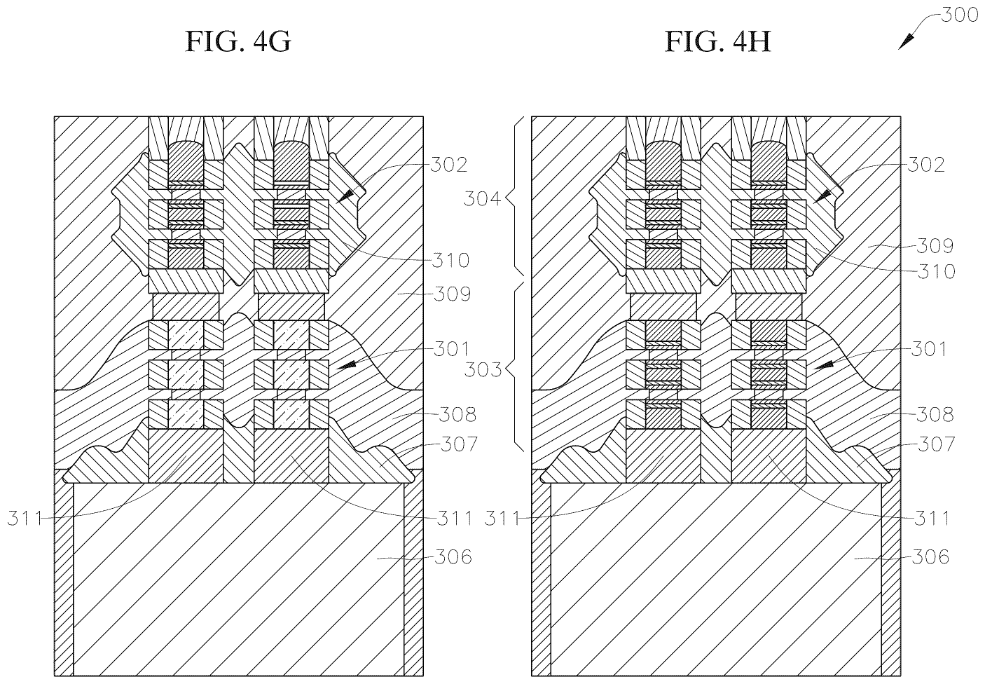

FIG. 3 is a flowchart depicting tasks of a method 200 of manufacturing a three-dimensional stacked transistor device 300 (e.g., the three-dimensional stacked transistor device 100 of FIGS. 1A-1B) according to one embodiment of the present disclosure, and FIGS. 4A-4G depict the three-dimensional stacked transistor device during the method 200 of FIG. 3. In the embodiment illustrated in FIGS. 3 and 4A, the method 200 includes a task 210 of forming a stack of channel regions 301, 302 of a lower field-effect transistor (FET) 303 and an upper FET 304, respectively, on a sacrificial layer 305 on a silicon substrate 306. The lower FET 303 may be one of an n-type FET (nFET) or a p-type FET (pFET), and the upper FET 304 may be the other of the nFET or the pFET. For instance, in one or more embodiments, the task 210 includes forming a channel region 301 of an nFET on the sacrificial layer 305 and a channel region 302 of a pFET on the channel region 301 of the nFET, or forming a channel region 301 of a pFET on the sacrificial layer 305 and a channel region 302 of an nFET on the channel region 301 of the pFET. Accordingly, in one or more embodiments, the method 200 may include forming the three-dimensional stacked transistor device such that the nFET is on (above) the pFET or such that the pFET is on (above) the nFET.

With reference now to FIGS. 3 and 4B, the method 200 also includes a task 220 of removing (e.g., etching) portions of the sacrificial layer 305 that are not covered by the channel region 301 of the lower FET 303 (e.g., etching exposed portions of the sacrificial layer 305). Following task 220, portions of the sacrificial layer 305 underneath the channel region 301 of the lower FET 303 remain and portions of the silicon substrate 306 are exposed. The task 220 of removing the portions of the sacrificial layer 305 may be performed in any suitable manner, such as wet or dry etching.

With reference now to FIGS. 3 and 4C, the method 200 also includes a task 230 of forming (e.g., epitaxially growing) a punch through stopper (PTS) layer 307 on the portions of the silicon substrate 306 that were exposed in task 220. In one or more embodiments, the PTS layer 307 may be doped with the opposite polarity of the lower FET 303. For instance, in one or more embodiments in which the lower FET 303 is an nFET, the PTS layer 307 is p-type doped. In one or more embodiments in which the lower FET 303 is a pFET, the PTS layer 307 is n-type doped. The PTS layer 307 is configured to improve the leakage current of the stacked three-dimensional transistor device compared to a related art CFET device.

With reference now to FIGS. 3 and 4D, the method 200 also includes a task 240 of forming (e.g., epitaxially growing) the source/drain regions 308 of the lower FET 303 on the PTS layer 307 formed in task 230. The source/drain regions 308 of the lower FET 303 have the opposite polarity of the PTS layer 307 formed in task 230. For instance, in one or more embodiments in which the PTS layer 307 is p-type doped, the source/drain regions 308 of the lower FET 303 are n-type doped. In one or more embodiments in which the PTS layer 307 is n-type doped, the source/drain regions 308 of the lower FET 303 are p-type doped. In one or more embodiments, the source/drain regions 308 of the lower FET 303 each include p-doped SiGe, and the PTS layer 307 includes n-doped SiGe. In one or more embodiments, the source/drain regions 308 of the lower FET 303 each include n-doped SiGe, and the PTS layer 307 includes p-doped SiGe. In one or more embodiments, the source/drain regions 308 of the lower FET 303 each include p-doped silicon, and the PTS layer 307 includes n-doped silicon. In one or more embodiments, the source/drain regions 308 of the lower FET 303 each include n-doped silicon, and the PTS layer 307 includes p-doped silicon.

With reference now to FIGS. 3 and 4E, the method 200 also includes a task 250 of forming (e.g., depositing) a dielectric material 309 to electrically isolate the lower FET 303 from the upper FET 304 and forming (e.g., epitaxially growing) the source/drain regions 310 of the upper FET 304 on the source/drain regions 308 of the lower FET 303 formed in task 240. The source/drain regions 310 of the upper FET 304 have the opposite polarity of the source/drain regions 308 of the lower FET 303 formed in task 240. For instance, in one or more embodiments in which the source/drain regions 308 of the lower FET 303 are p-type doped, the source/drain regions 310 of the upper FET 304 are n-type doped. In one or more embodiments in which the source/drain regions 308 of the lower FET 303 are n-type doped, the source/drain regions 310 of the upper FET 304 are p-type doped. In one or more embodiments, in task 250, the dielectric material 309 is deposited before the epitaxial growth of the source/drain regions 310 of the upper FET 304.

With reference now to FIGS. 3 and 4F, the method 200 also includes a task 260 of removing (e.g., etching, such as wet or dry etching) the remaining portions of the sacrificial layer 305. Following task 260, openings (voids) 310 are formed in the areas previously occupied by the sacrificial layer 305. Additionally, in task 260, a remaining portion of the dielectric material 309 is formed (e.g., deposited) after the source/drain regions 310 of the upper FET 304 are formed in task 250.

With reference now to FIGS. 3 and 4G, the method 200 includes a task 270 of forming a partial bottom dielectric isolation (BDI) layer 311 in the openings (voids) 310 formed in task 260. That is, task 270 includes filling (or at least substantially filling) the openings (voids) 310 formed in task 260 with a dielectric material. In the illustrated embodiment, the partial BDI layer 311 formed in task 270 is below the channel region 301 of the lower FET 303. In one or more embodiments, the partial BDI layer 311 does not extend underneath (or at least substantially does not extend underneath) the source/drain regions 308 of the lower FET 303. The partial BDI layer 311, which does not extend underneath the source/drain regions 308 of the lower FET 303, is configured to improve thermal dissipation compared to a related art transistor device having a full BDI layer that extends underneath the source/drain regions 308. In one or more embodiments, the method 200 may not include the task 270 of filling the openings (voids) 310 with a dielectric material, and the openings (voids) 310 may remain open (i.e., unfilled) and function as the partial BDI layer. As shown in FIG. 4H, the method 200 also includes one or more tasks of forming source/drain contacts and a gate contact to complete formation of the three-dimensional stacked transistor device 300.

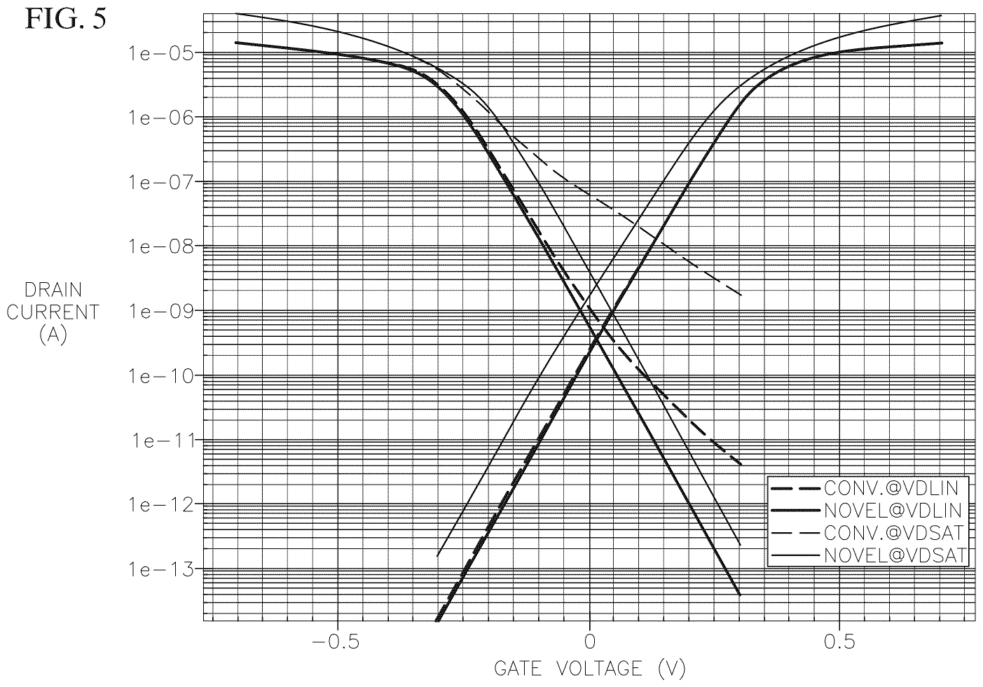

FIG. 5 is a graph depicting the drain current (Id) as a function of gate voltage (Vg) for a related art transistor device compared to a three-dimensional stacked transistor device according to one embodiment of the present disclosure that includes a partial BDI layer and a PTS layer. As illustrated in FIG. 5, the three-dimensional stacked transistor device according to one embodiment of the present disclosure (which includes a partial BDI layer and a PTS layer) exhibits reduced current leakage compared to the related art transistor device. For instance, as shown in FIG. 5, the drain current (i.e., the current flowing between the drain and source terminals of the transistor device) at the drain saturation voltage (“Vdsat”) for the transistor device of the present disclosure is less than the drain current at Vdsat for the related art transistor device for a gate voltage (V) ranging from approximately −0.15 V to approximately 0.3 V. Similarly, the drain current at the drain voltage for linear operation (“Vdlin”) for the transistor device of the present disclosure is less than the drain current at Vdlin for the related art transistor device for a gate voltage (V) ranging from approximately 0 V to approximately 0.3 V. Accordingly, the PTS layer (e.g., PTS layer 103 in FIGS. 1A-1B or PTS layer 307 in FIGS. 3 and 4A-4G) below the source/drain region of the lower transistor (e.g., the n-type doped region below the p-type doped epitaxial growth region) is configured to suppress bottom current leakage.

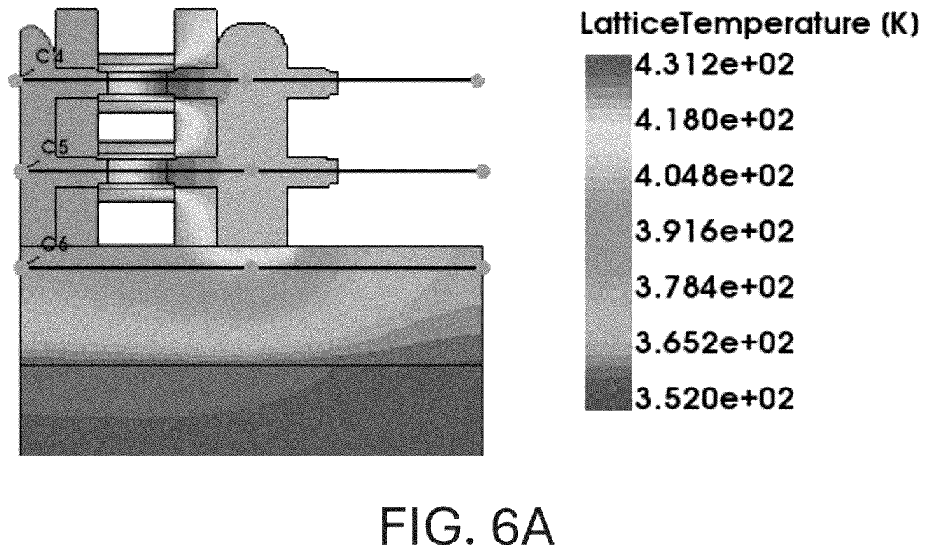

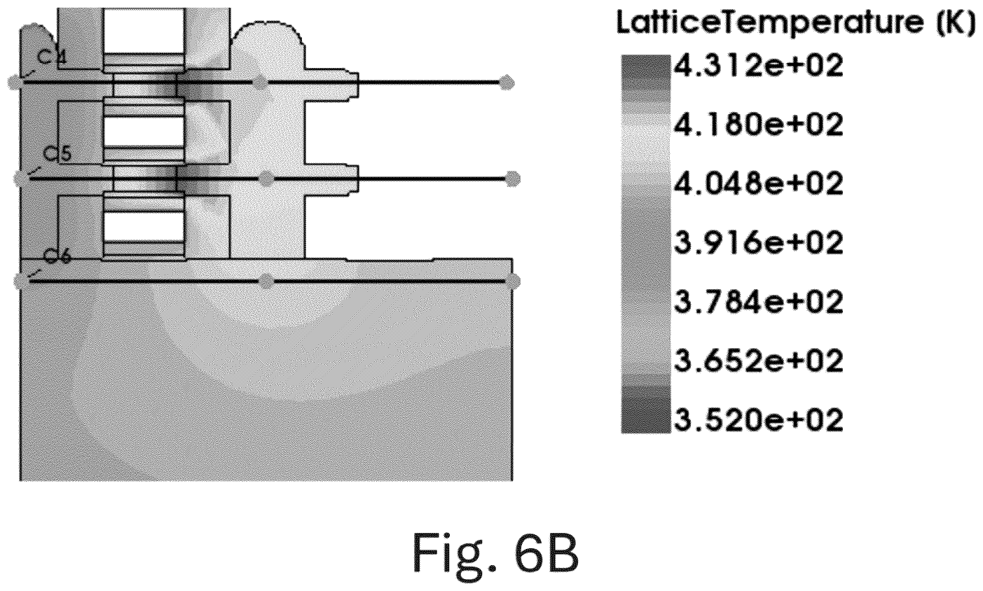

FIGS. 6A-6B are heat maps depicting the lattice temperature for a related art transistor device having a full bottom dielectric insulation layer and the lattice temperature for a three-dimensional stacked transistor device according to one embodiment of the present disclosure including a partial bottom dielectric insulation layer, respectively. As illustrated in FIG. 6A, in the related art transistor device having the full BDI layer (which extends completely underneath the source/drain regions of the lower transistor), the channel region has a lattice temperature of approximately 4.25e02 kelvin (K). In contrast, as illustrated in FIG. 6B, in the transistor device including a partial BDI layer (which does not, or substantially does not, extend underneath the source/drain regions of the lower transistor) according to embodiments of the present disclosure, the channel region has a lower lattice temperature of approximately 4.11e02 K. Accordingly, the partial BDI layer improves the thermal dissipation of the transistor device according to embodiments of the present disclosure compared to a related art device with a full BDI layer.

The PTS layer (e.g., PTS layer 103 in FIGS. 1A-1B or PTS layer 307 in FIGS. 3 and 4A-4G), which is epitaxially grown on the substrate before the source/drain regions of the lower FET are epitaxially grown, enables the channels to be stressed by the source/drain regions, which increases channel mobility (i.e., the PTS layer grown from the substrate enables the source/drain regions to be appropriately stress, which imparts compressive stress to the channel regions and thereby increases carrier mobility in the channel regions).

Although the embodiments in FIGS. 1A-4G depict a three-dimensional stacked transistor device, in one or more embodiments, the partial bottom dielectric isolation (BDI) layer and the punch through stopper (PTS) layer may be utilized in a single layer field-effect transistor (FET), such as a single nanosheet FET.

While this invention has been described in detail with particular references to exemplary embodiments thereof, the exemplary embodiments described herein are not intended to be exhaustive or to limit the scope of the invention to the exact forms disclosed. Persons skilled in the art and technology to which this invention pertains will appreciate that alterations and changes in the described structures and methods of assembly and operation can be practiced without meaningfully departing from the principles, spirit, and scope of this invention, as set forth in the following claims.

What is claimed is:

1. A method of manufacturing a transistor device, the method comprising:
forming a channel region of at least a first transistor on a sacrificial layer on a silicon substrate;
removing portions of the sacrificial layer;
epitaxially growing a punch through stopper layer on the silicon substrate and on opposite sides of a remaining portion of the sacrificial layer;
epitaxially growing a source region and a drain region of the first transistor on the punch through stopper layer; and
forming a partial bottom dielectric isolation layer comprising removing the remaining portion of the sacrificial layer to form at least one void.

2. The method of claim 1, wherein the transistor device is a complementary field-effect transistor, and wherein the forming the channel region comprises forming a first channel region of the first transistor and a second channel region of a second transistor stacked on the first transistor.

3. The method of claim 1, wherein the transistor device is a single layer field-effect transistor.

4. The method of claim 1, further comprising substantially filling the at least one void with a dielectric material.

5. The method of claim 1, wherein the partial bottom dielectric isolation layer does not extend under the source region or the drain region of the first transistor.

6. The method of claim 1, wherein the source region and the drain region of the first transistor each comprises p-doped SiGe, and wherein the punch through stopper layer comprises n-doped SiGe.

7. The method of claim 1, wherein the source region and the drain region of the first transistor each comprise n-doped SiGe, and wherein the punch through stopper layer comprises p-doped SiGe.

8. The method of claim 1, wherein the source region and the drain region of the first transistor each comprise p-doped silicon, and wherein the punch through stopper layer comprises n-doped silicon.

9. The method of claim 1, wherein the source region and the drain region of the first transistor each comprise n-doped silicon, and wherein the punch through stopper layer comprises p-doped silicon.

10. A field-effect transistor comprising:
a silicon substrate;
a partial bottom dielectric isolation layer on the silicon substrate;
a punch through stopper layer on the silicon substrate and on opposite sides of the partial bottom dielectric isolation layer;
a first transistor on the partial bottom dielectric isolation layer and the punch through stopper layer; and
wherein the first transistor comprises a channel, a source region on one side of the channel, and a drain region on another side of the channel,
wherein the partial bottom dielectric isolation layer is below the channel of the first transistor, and
wherein the punch through stopper layer is below the source region and the drain region of the first transistor.

11. The field-effect transistor of claim 10, further comprising a second transistor stacked on the first transistor.

12. The field-effect transistor of claim 10, wherein the partial bottom dielectric isolation layer comprises a dielectric material.

13. The field-effect transistor of claim 10, wherein the partial bottom dielectric isolation layer comprises a void.

14. The field-effect transistor of claim 10, wherein the partial bottom dielectric isolation layer does not extend under the source region or the drain region of the first transistor.

15. The field-effect transistor of claim 11, wherein the first transistor is a p-type field-effect transistor and the second transistor is an n-type field-effect transistor.

16. The field-effect transistor of claim 15, wherein the source region and the drain region of the first transistor each comprise p-doped SiGe, and wherein the punch through stopper layer comprises n-doped SiGe.

17. The field-effect transistor of claim 15, wherein the source region and the drain region of the first transistor each comprise p-doped silicon, and wherein the punch through stopper layer comprises n-doped silicon.

18. The field-effect transistor of claim 11, wherein the first transistor is an n-type field-effect transistor and the second transistor is a p-type field-effect transistor.

19. The field-effect transistor of claim 18, wherein the source region and the drain region of the first transistor each comprise n-doped SiGe, and wherein the punch through stopper layer comprises p-doped SiGe.

20. The field-effect transistor of claim 18, wherein the source region and the drain region of the first transistor each comprise n-doped silicon, and wherein the punch through stopper layer comprises p-doped silicon.
